(19) United States
(12) Patent Application Publication
(10) Pub. No.: US 2022/0111636 A1
(43) Pub. Date: Apr. 14, 2022

(54) PRINTHEAD HIGH SIDE SWITCH CONTROLS

(71) Applicant: Hewlett-Packard Development Company, L.P., Spring, TX (US)

(72) Inventors: Eric Thomas Martin, Corvallis, OR (US); Rogelio Cicili, San Diego, CA (US); Daryl E. Anderson, Corvallis, OR (US)

(73) Assignee: Hewlett-Packard Development Company, L.P., Spring, TX (US)

(21) Appl. No.: 17/413,679

(22) PCT Filed: Jun. 19, 2019
(86) PCT No.: PCT/US2019/037885

§ 371 Date: Jun. 14, 2021

(51) Int. Cl. B41J 2/045; H03K 17/687

(52) U.S. Cl. CPC B41J 2/0455; H03K 17/6872; H03K 2217/0081; B41J 2/04548; B41J 2/04541; B41J 2/0458

(57) ABSTRACT

In example implementations, an apparatus is provided. The apparatus includes a power supply, a first switch coupled, a second switch, and a second resistor. The first switch is coupled to the power supply and a low voltage control block. The second switch is coupled to the power supply and the first switch. The second resistor is coupled to the second switch to generate heat in response to being energized. The first switch is to control activation of the second switch via a fire signal from the low voltage control block and through the first resistor to energize the second resistor and cause a nozzle chamber to dispense a printing fluid.

### BACKGROUND

Printers are used to print images onto a print medium. Printers may print images using different types of printing fluids and/or materials. For example, some printers may use ink, toner, and the like. A print job may be transmitted to the printer and the printer may dispense the printing fluids and/or materials on the print medium in accordance with the print job.

### BRIEF DESCRIPTION OF THE DRAWINGS

FIG. 1 is a block diagram of a printer that is deployed with an example of the high side switch (HSS) control of the present disclosure;

FIG. 2 is a block diagram of an example nozzle chamber that is controlled by the HSS control of the present disclosure;

FIG. 3 is a block diagram of an example HSS control of the present disclosure;

FIG. 4 is a circuit diagram of an example HSS control of the present disclosure; and

FIG. 5 illustrates a flow chart of an example method to activate a thermal ink jet resistor using an HSS control of the present disclosure.

### DETAILED DESCRIPTION

Examples described herein provide a high side switch (HSS) control for a printhead. As discussed above, printers can use various types of systems and printing fluids to print images onto a print medium. One example can be a thermal ink jet (TIJ) printer that uses TIJ printheads. However, the present disclosure may apply to two-dimensional printers as well as three dimensional printers

A TIJ printhead may include a nozzle chamber that includes a TIJ resistor that can generate heat when energized. The heat generated from the TIJ resistor may heat the printing fluid to create a steam bubble inside of the nozzle chamber that pushes the drop of printing fluid out of the nozzle chamber.

Different types of controls can be used to control activation of the TIJ resistor. Examples of the controls may include a low side switch (LSS) control and a high side switch (HSS) control. The LSS may provide a lower relative cost in terms of an amount of silicon area allocated to the circuits for controlling the LSS and the LSS itself. However, in some cases the LSS may provide no energy regulation against variation in power supply voltage, can have a reduced resistor life due to constant bias between the ink at ground and resistor at a voltage input, and the functionality of an entire group of resistors can be compromised if a single resistor shorts out.

In contrast, the HSS may provide solutions to the above issues with the LSS control. Namely, the HSS may provide energy regulation, some isolation to reduce the bias, and isolate damage to a single resistor if the resistor shorts out. However, the HSS uses a field effect transistor (FET) level shifter that may consume more silicon space, and it may therefore cost more to produce than the LSS. For example, the level shifter can consume as much as thousands of square microns of silicon area per nozzle.

In addition, some HSS control designs can use custom fabricated transistors or devices (e.g., non-industry standard devices). These custom devices can make it difficult to efficiently fabricate the HSS controls using standard circuit manufacturing processes in the integrated circuit industry.

The present disclosure provides a circuit design for the HSS control that reduces the amount of silicon that is used by simplifying the level shifter of the HSS control. The simplified level shifter reduces the number of high voltage p-type metal oxide semiconductor (HVPMOS) elements in the level shifter. In addition, the HSS control of the present disclosure eliminates the components associated with a clamp circuit. The clamp circuit can be included to protect susceptible devices from over-voltage events in the case of a fault or defect.

In addition, the HSS control of the present disclosure uses standard devices rather than custom devices. As a result, the circuit manufacturing processes to build the HSS control may be more available and cheaper. The overall amount of silicon that is used is reduced, thereby reducing the overall cost of producing the HSS control of the present disclosure.

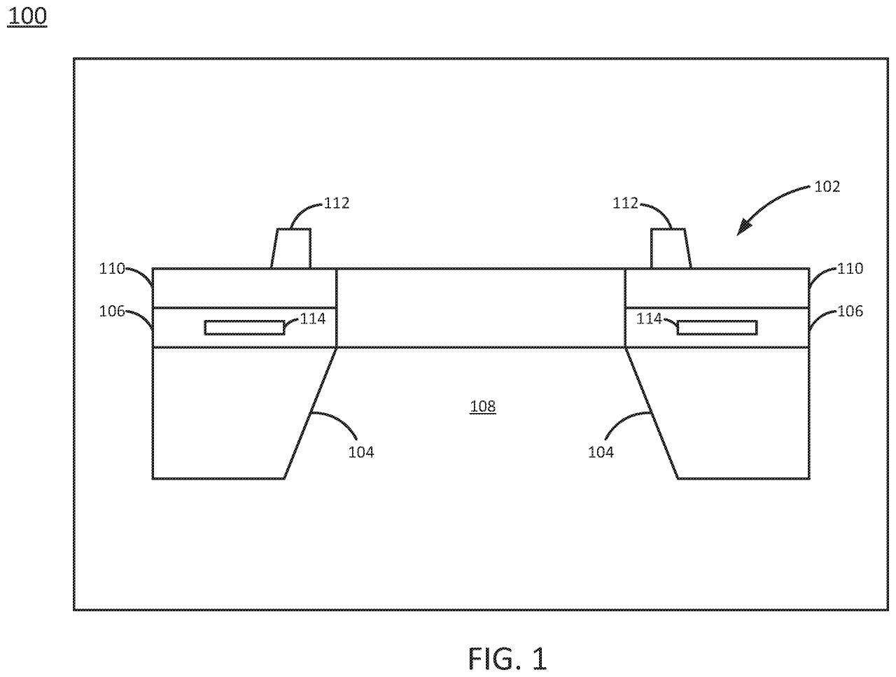

FIG. 1 illustrates an example printer 100 of the present disclosure. In one example, the printer 100 may be a thermal ink jet printer. The printer 100 has been simplified to show a cross-section of a fluidic die 102 used to eject printing fluid onto a print medium. The printer 100 may include additional components that are not shown, such as mechanical components associated with a print path, a feed module, a finishing module, a digital front end, a paper tray, reservoirs for the printing fluid, and the like.

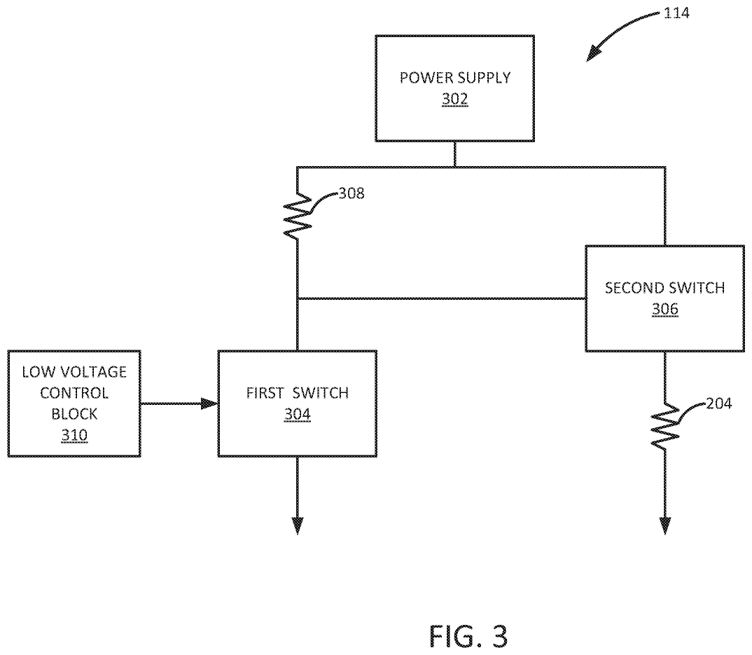

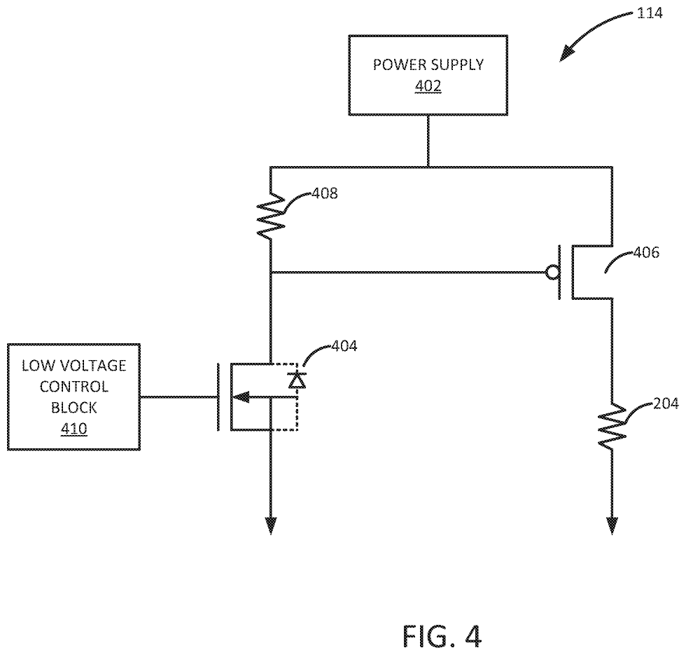

In one example, the fluidic die 102 includes a bulk silicon substrate 104. A layer of circuits 106 may be formed in and/or on the bulk silicon substrate 104. In one example, a high side switch (HSS) 114 of the present disclosure may be formed on the layer of circuits 106. The HSS control 114 may be used to control the ejection of printing fluid from a nozzle 112 of the fluidic die 102. Each nozzle 112 may be associated with a respective HSS control 114. In other words, the fluidic die 102 may include a plurality of HSS controls 114. The HSS control 114 of the present disclosure is illustrated in FIGS. 3 and 4 and discussed in further details below.

In one example, the fluidic die 102 may include an ink slot 108 and a layer of fluidics 110. Printing fluid may move through the ink slot to the desired nozzles 112 to be ejected onto a print medium.

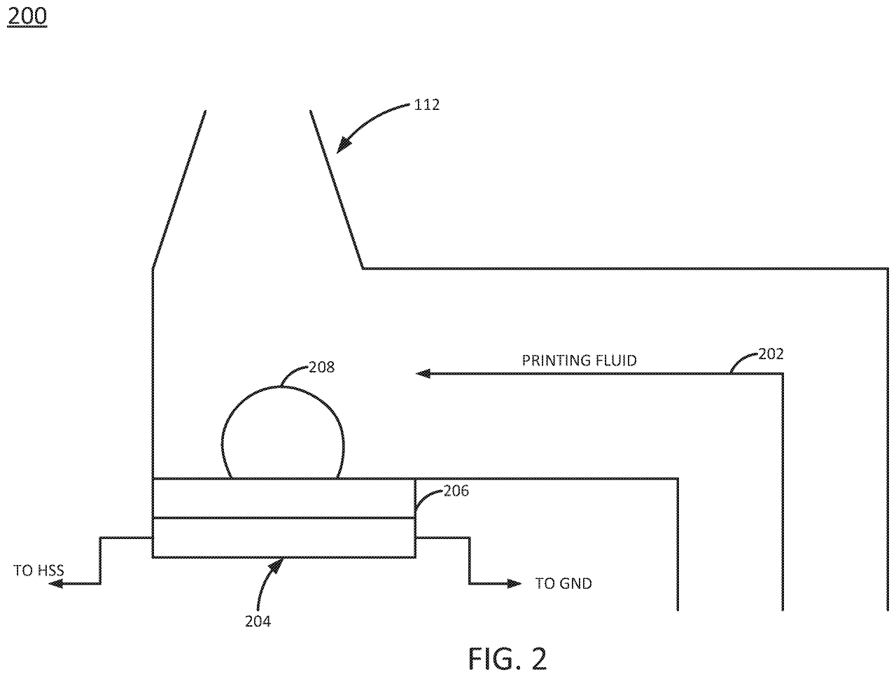

FIG. 2 illustrates a cross sectional view of an example nozzle chamber 200. Each nozzle 112 of the fluidic die 102 may be in fluid communication with a nozzle chamber 200. In one example, the nozzle chamber 200 may be coupled to the HSS control 114. A portion of the nozzle chamber 200 may include a conductive plate 206. The conductive plate 206 may be made of a conductive metal (e.g., tantalum). The conductive plate 206 may be electrically isolated from other components in the nozzle chamber 200.

In one example, a resistor 204 may be positioned adjacent to the conductive plate 206 (also known as a cavitation plate). In one example, an oxide layer may be grown between the resistor 204 and the conductive plate 206. When a printing fluid 202 is provided into the nozzle chamber 200, the resistor 204 may generate heat when activated to form a steam bubble 208. The steam bubble 208 may force the printing fluid 202 out of the nozzle 112.

The conductive plate 206 may protect the underlying structures from the forces associated with the steam bubble 208 forming and collapsing in the nozzle chamber 200. The conductive plate 206 may also prevent the printing fluid 202 from contacting the resistor 204 and other electrically insulating layers. If the printing fluid 202 were to contact the resistor 204, a short would be formed, which may cause the nozzle chamber 200 to malfunction.

In one example, the HSS control 114 of the present disclosure may be used to control activation of the resistor 204. As noted above, the HSS control 114 of the present disclosure provides a circuit design that is smaller and consumes less silicon in the bulk silicon substrate 104. The design of the HSS control 114 of the present disclosure does not include a circuit clamp and a test circuit, which can consume large amounts of the silicon in the bulk silicon substrate 104. Lastly, the design of the HSS control 114 may use standard components that are not custom built, and therefore, compatible with other manufacturing processes. As a result, the cost to build the HSS control 114, and the overall fluidic die 102 may be significantly reduced.

FIG. 3 illustrates a block diagram of an example of the HSS control 114 of the present disclosure. In one example, the HSS control 114 includes a power supply 302. The power supply 302 may be a high voltage power supply that provides high voltage. For example, the high voltage may be approximately greater than 10 volts. In one example, the high voltage may be approximately 30 volts.

A first switch 304 may be coupled to the power supply 302 via a first resistor 308. The first switch 304 may be a low voltage switch and may be coupled to a low voltage control block 310. The low voltage control block 310 may convert low voltage into a digital signal having a value of 0 or 1. In one example, the low voltage may be between 0-5 volts or 0-3.3 volts.

In one example, a low voltage switch may be a switch that can switch high voltage (e.g., 30 volts), but is controlled with a low voltage signal. A low voltage signal may be a signal that switches between 0 and 5 volts or 0 and 3.3 volts.

In one example, a second switch 306 may be a high voltage switch and may be coupled to the power supply 302. A second resistor 204 may be coupled to the second switch 306. The second resistor 204 may be the same resistor 204 illustrated in FIG. 2 to generate heat and create the steam bubble 208 to eject the printing fluid 202 out of the nozzle 112.

In one example, a high voltage switch may be a switch that can switch high voltage (e.g., 30 volts), but is controlled by a control signal that varies between a high voltage and a voltage threshold set by the low voltage signal. For example, if the high voltage is 30 volts and the low voltage signal is approximately 3.3 volts, then the high voltage switch may be controlled by a control signal that varies between 30 volts and approximately 27 volts.

In one example, the first resistor 308 may be referred to as a pull-up or pull-down resistor. The pull-up resistor may be deployed with a resistance value to provide a desired voltage threshold to operate the second switch 306. The first resistor 308 may also be sized and fabricated from a material that limits the current without significantly delaying a turn-off/turn-on time of the second switch 306. In one example, the first resistor 308 may toggle the control pin or gate of the second switch 306 between approximately 30 and 27 volts.

In one example, the first switch 304 may control operation of the second switch 306 based on a low signal (e.g., a digital signal having a value of 0) or a high signal (e.g., a digital signal having a value of 1) received from the low voltage control block 310. For example, when the voltage across the second switch 306 remains high or at 30 volts, the second switch 306 may remain off or deactivated. When the second switch 306 is off, no current may flow through the second resistor 204.

When the respective nozzle chamber 200 is to eject the printing fluid 202, the low voltage control block 310 may send a high signal to activate the first switch 304. When, the first switch 304 is activated, the first switch 304 may allow current to flow through the first resistor 308. The current flowing through the first resistor 308 may pull-down the voltage on the control pin or gate of the second switch 306 from 30 volts to 27 volts. At 27 volts, the second switch 306 may be activated.

When the second switch 306 is activated, the second switch 306 may couple the power supply 302 to the second resistor 204 to allow current to flow through the second resistor 204. The current flowing through the second resistor 204 may energize the second resistor 204, generate heat, and cause the nozzle chamber 200 to dispense the printing fluid 202.

In one example, the signal may be a digital signal based on the voltage provided from the low voltage power supply. For example, a voltage of 0 volts may be associated with a disable signal or a zero signal. A voltage of 3.3 volts may be associated with an enable signal or a one signal.

Although a single power supply 302 is illustrated in FIG. 3, it should be noted that multiple power supplies 302 may be deployed. For example, one power supply may be coupled to the first resistor 308 and a second power supply may be coupled to the second resistor 204. The separate power supplies may be used to trade off different levels of voltage regulation for power and thermal efficiency.

FIG. 4 illustrates a circuit diagram of an example of the HSS control 114 of the present disclosure. In one example, the HSS control 114 includes a power supply 402. The power supply 402 may provide high voltage. For example, the high voltage may be approximately greater than 10 volts. In one example, the high voltage may be approximately 30 volts.

A laterally diffused metal oxide semiconductor (LDMOS) switch 404 may be coupled to the power supply 402 via a pull-up resistor 408. The pull-up resistor 408 may be coupled to a drain of the LDMOS switch 404. The LDMOS switch 404 may be an n-type, low voltage switch and may be coupled to a low voltage control block 410. The low voltage control block 410 may generate a digital signal having a value of 0 or 1 corresponding to a low voltage range. In one example, the low voltage range may be between 0-5 volts or 0-3.3 volts.

In one example, a high voltage p-type metal oxide semiconductor (HVPMOS) switch 406 may be a high voltage switch and may be coupled to the power supply 402. It should be noted that in contrast to other high side switch designs that use an n-type LDMOS, the HSS control 114 of the present disclosure uses the HVPMOS switch 406. Using the HVPMOS switch 406 may avoid the use of a level shifter to drive the gate controlling the heat resistor 204.

In one example, the heat resistor 204 may be coupled to the HVPMOS switch 406. The heat resistor 204 may be the same resistor 204 illustrated in FIG. 2 to generate heat and create the steam bubble 208 to eject the printing fluid 202 out of the nozzle 112. The heat resistor 204 may also be referred to as a thermal ink jet (TIJ) resistor.

In one example, the pull-up resistor 408 (also referred to as a pull-down resistor 408 based on how the voltages are controlled) may be deployed with a resistance value to provide a desired voltage threshold to operate the HVPMOS switch 406. The pull-up resistor 408 may also be sized and fabricated from a material that limits the current without significantly delaying a turn-off/turn-on time of the HVPMOS switch 406. In one example, the pull-up resistor 408 may toggle the control pin or gate of the HVPMOS switch 406 between approximately 30 and 27 volts.

In one example, the LDMOS switch 404 may control operation of the HVPMOS switch 406 based on a low signal (e.g., a digital signal having a value of 0) or a high signal (e.g., a digital signal having a value of 1) received from the low voltage control block 410. For example, when the HVPMOS switch 406 is exposed to the maximum voltage of the power supply 402 (e.g., 30 volts), the HVPMOS switch 406 may remain off or deactivated. When the HVPMOS switch 406 is off, no current may flow through the heat resistor 204.

When, the respective nozzle chamber 200 is to eject the printing fluid 202, the low voltage control block 410 may send a high signal to activate the LDMOS switch 404. When, the LDMOS switch 404 is activated, the LDMOS switch 404 may allow current to flow through the pull-up resistor 408. The current flowing through the pull-up resistor 408 may pull-up or pull-down the voltage of the HVPMOS switch 406 from the maximum voltage of the power supply 402 to a voltage that is equal to the maximum voltage less a voltage threshold determined by the pull-up resistor 408. In one example, the maximum voltage may be approximately 30 volts and the voltage threshold may be approximately 3 volts. Thus, a voltage of 27 volts may cause the HVPMOS switch 406 to be activated.

When the HVPMOS switch 406 is activated, the HVPMOS switch 406 may couple the power supply 402 to the heat resistor 204 to allow current to flow through the heat resistor 204. The current flowing through the heat resistor 204 may energize the heat resistor 204, generate heat, and cause the nozzle chamber 200 to dispense the printing fluid 202.

Although a single power supply 402 is illustrated in FIG. 4, it should be noted that multiple power supplies 402 may be deployed. For example, one power supply may be coupled to the pull-up resistor 408 and a second power supply may be coupled to the heat resistor 204. The separate power supplies may be used to trade off different levels of voltage regulation for power and thermal efficiency.

The design of the HSS control 114 illustrated in FIGS. 3 and 4 uses non-customized off-the-shelf components that are available using other circuit manufacturing processes, such as CMOS integrated circuit processes. In addition, the design of the HSS control 114 of the present disclosure reduces the number of high voltage switches (e.g., the HVPMOS switches). The high voltage switches may consume a large amount of silicon and add to the cost of a high side switch. The HSS control 114 of the present disclosure uses a single high voltage switch.

In addition, the design of the HSS control removes the clamp circuit, which can also consume a large amount of silicon and be expensive to manufacture. For example, the HVPMOS switch 406 that controls the heat resistor 204 may be tolerant to high voltages between the gate and drain. As a result, even if the pull-up resistor 408 were to short to ground, the HVPMOS switch 406 may be able to tolerate the resultant high voltage between the gate and the drain of the HVPMOS switch 406.

Furthermore, the design of the HSS control 114 may remove the testing circuit, which can also consume a large amount of silicon. The nozzle chamber 200 of each nozzle 112 may be tested during use or manufacture. Testing may enable the heat resistor 204 for a relatively long period of time (e.g., micro seconds during testing versus nanoseconds during operation). When the heat resistor 204 is exposed to large currents over a long period of time, the heat resistor 204 may be damaged or may fail during the testing. The HVPMOS switch 406 may allow a small amount of current at low voltages to be passed through to the heat resistor 204 to prevent the heat resistor 204 from being damaged during testing. Thus, the design of the HSS control 114 provides a smaller, less expensive design than other high side switches.

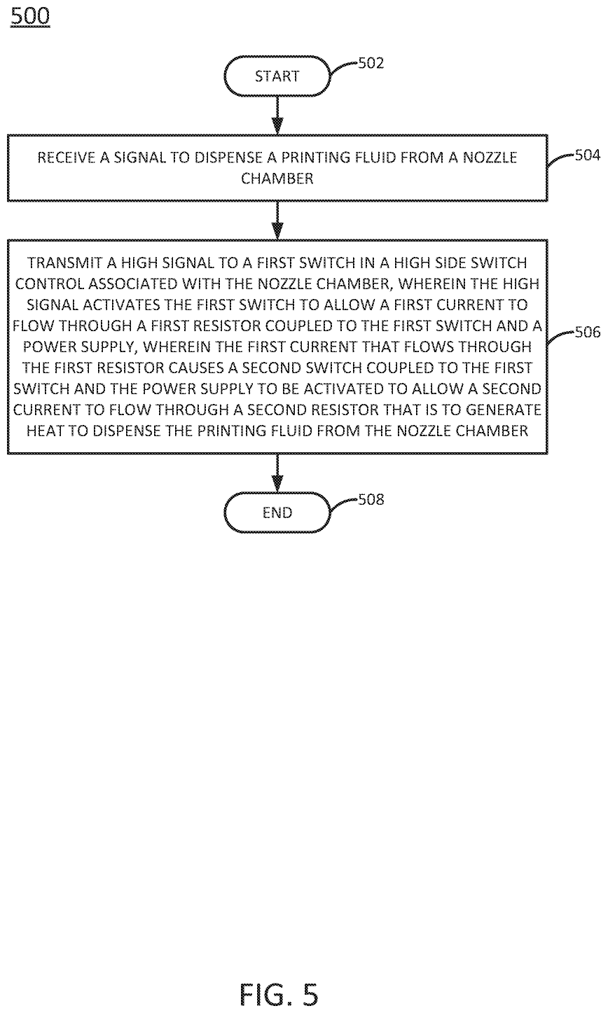

FIG. 5 illustrates a flow chart of an example method to activate a thermal ink jet resistor using an HSS control of the present disclosure. In an example, the method 500 may be performed by a controller or processor of the printer 100 illustrated in FIG. 1.

At block 502, the method 500 begins. At block 504, the method 500 receives a signal to dispense a printing fluid from a nozzle chamber. For example, a printer may be activated to print a desired image onto a print medium. A printer may determine locations on the print medium to dispense a printing fluid. The printing fluid may be dispensed via nozzle chambers in a fluidic die.

At block 506, the method 500 transmits a high signal to a first switch in a high side switch control associated with the nozzle chamber, wherein the high signal activates the first switch to allow a first current to flow through a first resistor coupled to the first switch and a power supply, wherein the first current that flows through the first resistor causes a second switch coupled to the first switch and the power supply to be activated to allow a second current to flow through a second resistor that is to generate heat to dispense the printing fluid from the nozzle chamber. For example, the printer may cause a low voltage power source to generate a low voltage signal that is associated with a digital one signal, or the high signal.

When the first switch is activated, current from the power supply may be allowed to flow through the first resistor. The first resistor may pull-down the voltage across the control pin or gate of the second switch from a maximum voltage to a voltage that is the maximum voltage less a voltage threshold set by the first resistor. In one example, the maximum voltage may be approximately 30 volts, the voltage threshold may be approximately 3 volts, and the voltage to activate the second switch may be approximately 27 volts.

When the second switch is activated, current may be allowed to flow from the power source, through the second switch, and through the second resistor, or the TIJ resistor. The current flowing through the second resistor may cause the second resistor to generate heat. The heat may cause a steam bubble to be formed inside of the nozzle chamber. The steam bubble may force the printing fluid through the nozzle and out of the nozzle chamber onto the print media.

In one example, a signal to stop the printing fluid from dispensing from the nozzle chamber may be received. For example, printing may be completed at a particular location of the print media for the print job.

In response to the signal to stop the printing fluid from dispensing, the printer may cause the low voltage control block to change its output to a disabled state. In the disabled state a digital zero signal or a low signal may be generated. The low signal may deactivate the first switch, which may prevent current from the power supply from flowing through the first resistor. When the current is removed from the first resistor, the voltage across the second switch may return to the maximum voltage to deactivate the second switch. Deactivating the second switch may stop the current from the power supply from flowing through the second resistor. As a result, the second resistor may stop generating heat, which may eliminate the formation of the steam bubble, and prevent the printing fluid from being ejected out of the nozzle chamber. At block 508, the method 500 ends.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An apparatus, comprising:
a power supply;
a first switch coupled to the power supply via a first resistor and a low voltage control block;
a second switch coupled to the power supply and the first switch; and
a second resistor coupled to the second switch to generate heat in response to being energized, wherein the first switch is to control activation of the second switch via a fire signal from the low voltage control block and through the first resistor to energize the second resistor and cause a nozzle chamber to dispense a printing fluid.

2. The apparatus of claim 1, wherein the power supply comprises a high voltage power supply that provides greater than 10 Volts.

3. The apparatus of claim 1, wherein the first switch comprises a low voltage switch.

4. The apparatus of claim 1, wherein the second switch comprises a high voltage switch.

5. The apparatus of claim 1, wherein the second switch is to be deactivated and receive a high voltage in response to the first switch receiving a low signal and no current being provided through the first resistor.

6. The apparatus of claim 1, wherein the second switch is to be activated and receive a low voltage in response to the first switch receiving a high signal and current being provided through the first resistor.

7. An apparatus, comprising:
a power supply;
a laterally diffused metal oxide semiconductor (LDMOS) switch coupled to the power supply via a pull-up resistor and a low voltage control block;
a high voltage p-type metal oxide semiconductor (HVPMOS) switch coupled to the power supply and the LDMOS switch; and
a heat resistor coupled to the HVPMOS switch to generate heat in response to being energized, wherein the LDMOS switch is to control activation of the HVPMOS switch via a fire signal from the low voltage control block and through the pull-up resistor to energize the heat resistor and cause a nozzle chamber to dispense a printing fluid.

8. The apparatus of claim 7, wherein the LDMOS switch comprises an n-type device.

9. The apparatus of claim 7, wherein the pull-up resistor is coupled to the power supply and a source of the LDMOS.

10. The apparatus of claim 7, wherein the power supply is coupled to a drain of the HVPMOS.

11. The apparatus of claim 7, wherein a gate of the HVPMOS switch is to be deactivated in response to exposure to a maximum voltage of the power supply.

12. The apparatus of claim 7, wherein the HVPMOS switch is activated in response to exposure to the maximum voltage less a voltage threshold.

13. The apparatus of claim 12, wherein the voltage threshold is to be based on a resistance of the pull-up resistor.

14. A method comprising:
receiving, by a processor, a signal to dispense a printing fluid from a nozzle chamber; and
transmitting, by the processor, a high signal to a first switch in a high side switch control associated with the nozzle chamber, wherein the high signal activates the first switch to allow a first current to flow through a first resistor coupled to the first switch and a power supply, wherein the first current that flows through the first resistor causes a second switch coupled to the first switch and the power supply to be activated to allow a second current to flow through a second resistor that is to generate heat to dispense the printing fluid from the nozzle chamber.

15. The method of claim 14, further comprising:
receiving, by the processor, a signal to stop the printing fluid from dispensing from the nozzle chamber; and
transmitting, by the processor, a low signal to the first switch, wherein the low signal deactivates the first switch to remove the first current from the first resistor, wherein the second switch is to deactivate in response to the first current being removed from the first resistor to remove the second current from the second resistor.
